(19) United States
(12) Patent Application Publication
(10) Pub. No.: US 2006/0071697 A1
(43) Pub. Date: Apr. 6, 2006

(54) Pwm generator

(75) Inventor: Frank Kamiel Irena Mels, Brugge (BE)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/535,288

(22) PCT Filed: Oct. 29, 2003
(86) PCT No.: PCT/IB03/04890

§ 371 Date: May 17, 2005

(30) Foreign Application Priority Data
Nov. 22, 2002 (EP) 02079943.3

(51) Int. Cl. H03K 3/017; H03K 5/04

(52) U.S. Cl. 327/175

(57) ABSTRACT

A PWM generator (100; 200; 300; 400) is described, which does not require a separate saw-tooth generator and a separator for generating a modulated pulsed signal. According to the invention, the input signal (Sᵢₙ) is supplied to one input terminal (111) of a comparator (110), which receives at its other terminal (112) a feedback signal which is derived from the output signal (Sₒᵤₜ) via an integrator device (150), in such a way that the circuit is self-oscillating. The feedback signal is a sloping signal. The comparator switches its output when the feedback signal crosses the level of the input signal, which in turn causes the feedback signal to invert its slope. Thus, the feedback signal in effect provides a saw-tooth signal without being generated by a separate saw-tooth generator.

The present invention relates in general to a PWM (Pulse Width Modulation) generator, which may be suitable for use in a switching amplifier (for instance, Class D audio amplifiers, servo systems, DC motor drives, supplies). The invention also relates to an electronic apparatus comprising the PWM generator.

A PWM generator is a device which converts an analog input signal into a pulsed output signal, which can take only two signal values, which will be indicated as HIGH and LOW. The HIGH signal value and the LOW signal value remain substantially constant. The duty cycle of the output signal depends on the input signal, such that an average value of the output signal varies in accordance with the input signal.

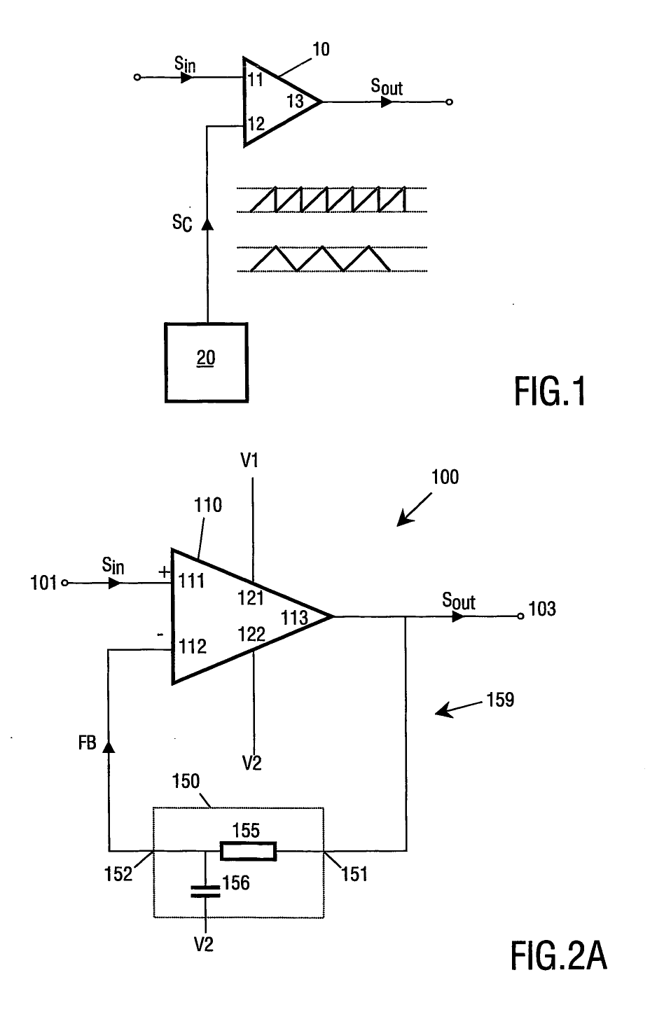

The design of a conventional PWM generator is illustrated in FIG. 1. A comparator 10 receives at its first input 11 (in this case: non-inverting input) the analog input signal Sᵢₙ, and receives at its other input 12 (in this case: inverting input) a control signal S_{c}, typically having a sawtooth or triangular shape, generated by a control signal generator 20 (saw-tooth generator). At its output 13, the comparator 10 provides a PWM output signal Sₒᵤₜ, which has either a HIGH value (if the present input signal value is higher than the present control signal value) or a LOW value (if the present input signal value is less than the present control signal value). If the present input signal value is relatively low, the output signal Sₒᵤₜ is HIGH during a relatively short time and LOW during a relatively long time (the duty cycle is less than 50%), so that the average value of the output signal Sₒᵤₜ is relatively low, reflecting the low input signal value. Conversely, if the present input signal value is relatively high, the output signal Sₒᵤₜ is HIGH during a relatively long time and LOW during a relatively short time (the duty cycle is more than 50%), so that the average value of the output signal Sₒᵤₜ is relatively high, reflecting the high input signal value. The frequency of the cycle is determined by the frequency of the control signal S_{c}.

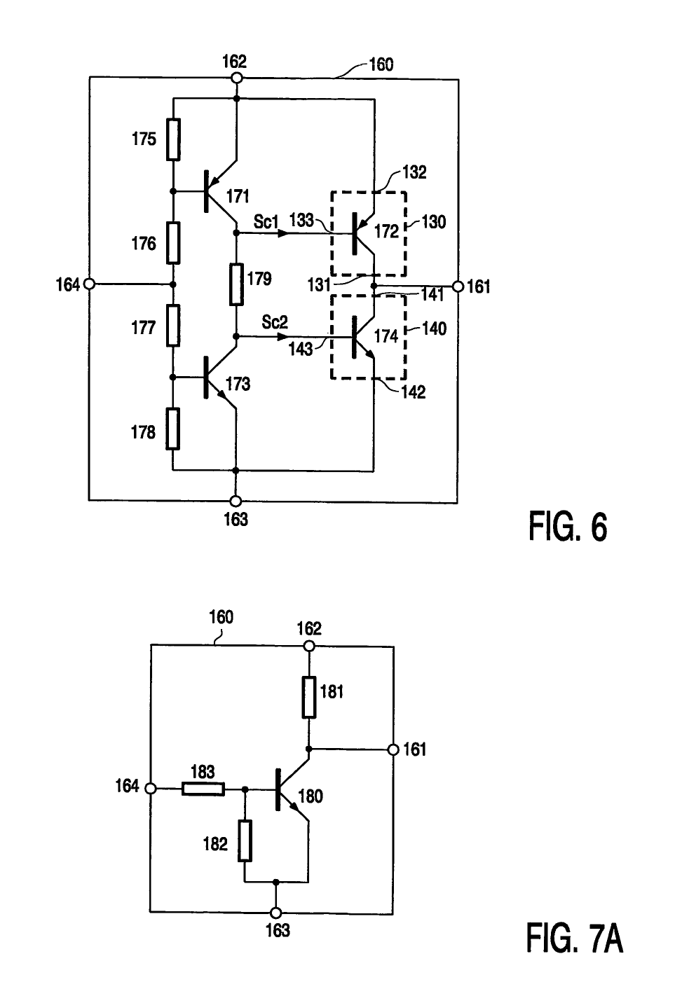

By way of example, it is noted that an example of such conventional PWM generator is disclosed in the document Motorola Semiconductor Application Note AN1042/D, “High Fidelity Switching Audio Amplifiers Using TMOS Power MOSFETs” by Donald E. Pauly, 1989, FIG. 6.

A disadvantage of this conventional setup is that it requires two or more separate functional units, i.e. a comparator, a control signal generator, etc., which makes this design relatively complicated and costly.

Therefore, the present invention aims to provide a PWM generator with reduced complexity.

More particularly, the present invention aims to provide a PWM generator which requires a reduced number of components.

Still more particularly, the present invention aims to provide a PWM generator which does not require a separate control signal generator.

According to an important aspect of the present invention, a PWM generator comprises a self-oscillating multi vibrator having a control input for controlling the duty cycle, wherein the input signal Sᵢₙ is received at this control input.

In another important aspect of the present invention, a PWM generator comprises a comparator having one input for receiving an input signal, and further having an integrating feedback loop coupled between an output node and another comparator input. The PWM generator may be used in an electronic apparatus such as an audio amplifier and as a sound amplifier in a display device such as a television set or monitor.

The invention is defined by the independent claims. The dependent claims define advantageous embodiments.

These and other aspects, features and advantages of the present invention will be further explained by the following description of exemplary embodiments of a PWM generator according to the present invention with reference to the drawings, in which same reference numerals indicate same or similar parts, and in which:

FIG. 1 is a block diagram schematically illustrating a conventional PWM generator;

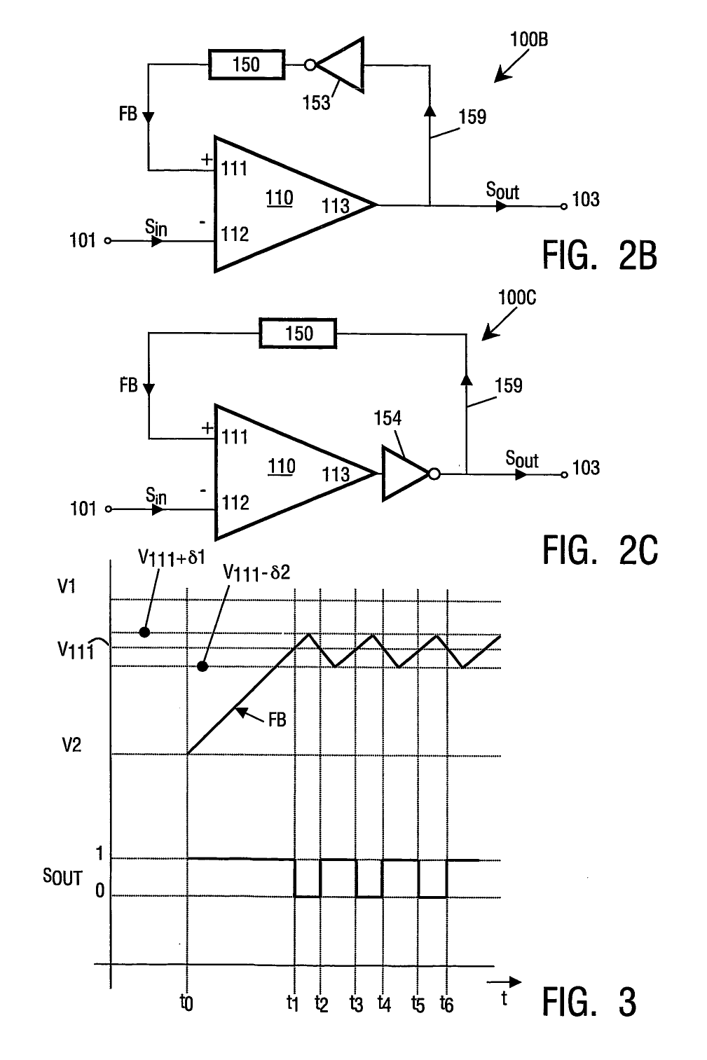

FIGS. 2A-2C are block diagrams schematically illustrating the basic design of a PWM generator in accordance with the present invention;

FIG. 3 is a graph illustrating the operation of the PWM generator in accordance with the present invention;

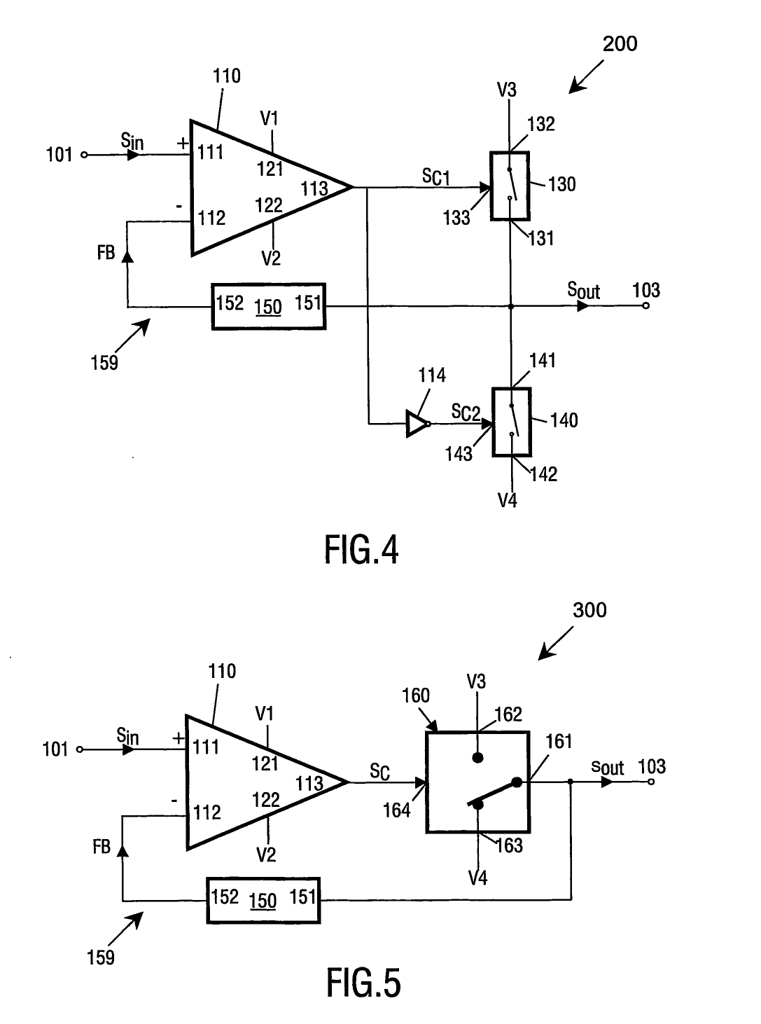

FIG. 4 is a block diagram schematically illustrating an embodiment of a PWM generator in accordance with the present invention;

FIG. 5 is a block diagram schematically illustrating another embodiment of a PWM generator in accordance with the present invention;

FIG. 6 illustrates an embodiment of a switch for use in the PWM generator of FIG. 5;

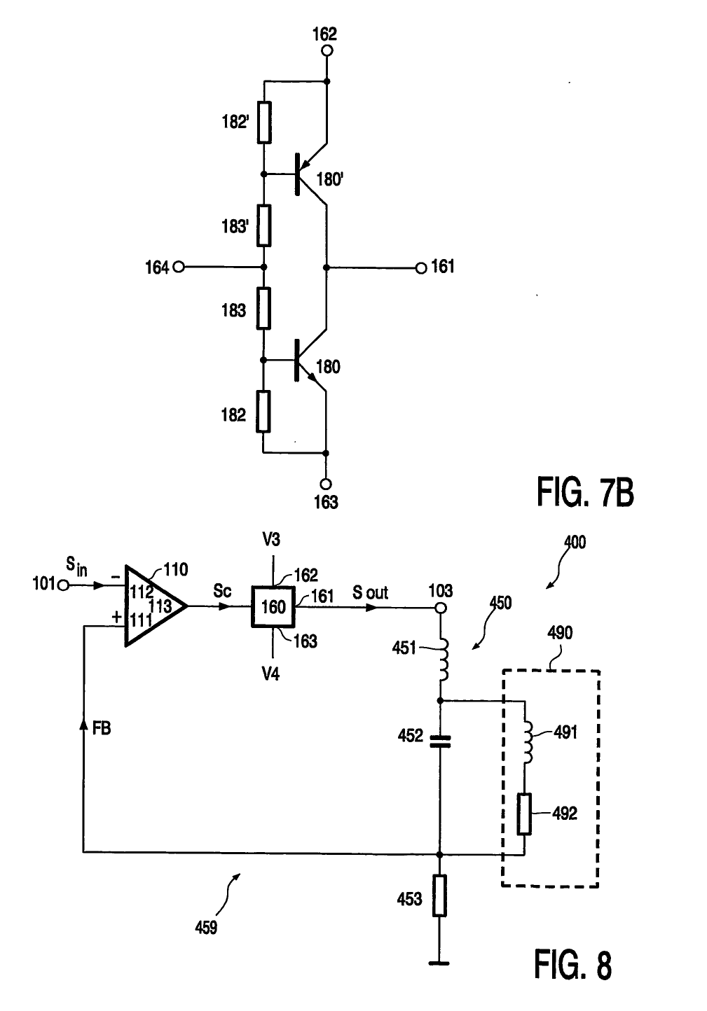

FIGS. 7A and 7B illustrate embodiments of an alternative switch with inverting properties;

FIG. 8 is a block diagram schematically illustrating another embodiment of a PWM generator in accordance with the present invention.

FIG. 2A schematically illustrates the basic design of an embodiment of a PWM generator 100 in accordance with the present invention. The PWM generator 100 comprises a comparator 110 having a first, non-inverting input 111 and a second, inverting input 112, and an output 113. The PWM generator 100 has an input terminal 101, coupled to the first comparator input 111, for receiving an analog input signal Sin. An output terminal 103 of the generator 100 is connected to the output 113.

Also, the comparator 110 has a first supply input terminal 121 and a second supply input terminal 122, for receiving operating supply voltages V1 and V2. In the following, it is assumed that V1 has higher voltage level than V2. V1 may be a positive voltage, while V2 may be any voltage (positive, zero Volt or mass, negative) lower than V1. On the other hand, V2 may be a negative voltage, while V1 may be any voltage (positive, zero Volt or mass, negative) higher than V2. Typically, V2 will be taken equal to a reference voltage level of the input signal for the capacitor 156.

The comparator 110 is designed to generate an output voltage at its output 113, having either a HIGH value (typically substantially equal to the first supply voltage V1) if the voltage level at its first input 111 is higher than the voltage level at its second input 112, or a LOW value (typically substantially equal to the second supply voltage V1) if the voltage level at its first input 111 is lower than the voltage level at its second input 112. Since such comparators are generally known, and a prior art comparator may be used in implementing the PWM generator according to the present invention, it is not necessary here to discuss the design and operation of the comparator in more detail.

The PWM generator 100 further comprises a feedback loop 159 from the generator output terminal 103 to the second comparator input 112. In the embodiment shown, the feedback loop 159 comprises an integrator 150 having an integrator input 151 coupled to the generator output terminal 103 and having an integrator output 152 coupled to the second comparator input 112. A function of the integrator 150 is to provide a relatively slowly rising or falling feedback signal FB at its integrator output 152 in response to a step-voltage received at its input 151. The integrator 150 may, for instance, be implemented as a low-pass filter. In a relatively simple embodiment, the integrator 150 may be implemented as a combination of a resistor 155 and a capacitor 156, as schematically indicated in FIG. 2A.

FIG. 3 is a graph illustrating the operation of the PWM generator 100. This graph shows the integrator output voltage being the feedback signal FB, of the integrator 150 and the output terminal voltage Sₒᵤₜ at the output terminal 103 as a function of time t. It is assumed that at time t=0 the voltage at the second input 112 is equal to V2, while the voltage at the first input 111 has a certain value V₁₁₁ between V2 and V1. Because the voltage level at its first input 111 is higher than the voltage level at its second input 112, the comparator 110 will then output a HIGH output level at its output 113.

Now, the integrator input 151 receives a HIGH voltage while the integrator output 152 is LOW. In such case, the integrator output voltage FB will slowly rise. At a certain moment t1, the integrator output voltage FB exceeds the voltage V₁₁₁ at the first input 111. Then, since the voltage level at the first comparator input 111 is lower than the voltage level at the second input 112, the comparator 110 generates a LOW output voltage.

Now, the integrator input 151 receives a LOW voltage while the integrator output 152 has a level between V2 and V1. In such case, the integrator output voltage FB will slowly decrease. However, before actually decreasing, the integrator output voltage FB will have increased with a certain overshoot ε1 above V₁₁₁, due to inevitable delay, as shown in an exaggerated manner in FIG. 3. At a certain moment t2, the integrator output voltage FB will fall below the voltage V₁₁₁ at the first input 111. Then, since the voltage V₁₁₁ level at the first input 111 is higher than the voltage level at the second input 112, the comparator 110 generates a HIGH output voltage. Again, due to inevitable delay, the integrator output voltage FB will show a certain undershoot δ2 below V₁₁₁.

The above cycle repeats itself, the output 113 switching from HIGH to LOW at times t1, t3, t5, etc, and switching from LOW to HIGH at times t2, t4, t6, etc.

Now, the duration of the HIGH period of the output 113 and the duration of the LOW period of the output 113 depend on the voltage level V₁₁₁ at the first input 111, i.e. the input signal value Sᵢₙ, in such a way that the average of the comparator output signal Sₒᵤₜ is substantially proportional to the voltage level at the first input 111. This can be understood as follows.

In the period from t1 to t2, capacitor 156 will be discharged by a discharge current i_{D} which is proportional to the voltage drop over the resistor 155, i.e. i_{D}˜V₁₁₁−V₂. In the period from t2 to t3, capacitor 156 will be charged by a charging current i_{C} which is likewise proportional to the voltage drop over the resistor 155, i.e. i_{C}˜V₁—V₁₁₁. The higher the level of V₁₁₁, the more the discharge current i_{D} will increase and the more the charging current i_{C} will decrease, hence the charging period t2-t3 will last longer while the discharge period t1-t2 will last shorter.

The set-up of FIG. 2A is self-oscillating. If the generator output at output terminal 103 is HIGH, the integrator 150 will generate a sloping feedback signal FB with a positive slope, which is received by the second input 112 of the comparator 110, such that, after a delay determined inter alia by the slope of the feedback signal FB, the rising voltage at the second input 112 will cause the comparator 110 to switch and generate a LOW output signal Sₒᵤₜ. Conversely, if the generator output at output terminal 103 is LOW, the integrator 150 will generate a sloping feedback signal FB with a negative slope, which is received by the second input 112 of the comparator 110, such that, after some delay, the falling voltage at the second input 112 will cause the comparator 110 to switch and generate a HIGH output signal Sₒᵤₜ.

The above operation repeats itself, thus causing the generator output signal Sₒᵤₜ to oscillate by itself The oscillation frequency is determined inter alia by the slope of the feedback signal FB, which, in the embodiment of the integrator 150 illustrated in FIG. 2A, mainly depends on the RC value of the resistor 155 and the capacitor 156. The switching level, which determines the duty cycle of the oscillating output signal Sₒᵤₜ, is controlled by the input signal Sᵢₙ received at the first input 111. Thus, the PWM generator 100 may also be considered to implement an example of a self-oscillating vibrator with a control input 111 for controlling the duty cycle.

In the embodiments as discussed above, the input signal Sᵢₙ is coupled to the non-inverting input 111 of the comparator 110, while the feedback signal FB is applied to the inverting input 112 of the comparator 110; then, as mentioned above, the switching arrangement should be such that the PWM output signal Sₒᵤₜ is HIGH when the input signal Sᵢₙ has a higher voltage level than the delayed PWM output signal Sₒᵤₜ. However, such setup is not essential for achieving the property of self-oscillation. Alternatively, it is also possible that the feedback signal FB is applied to the non-inverting input 111 of the comparator 110, whereas the input signal Sᵢₙ is applied to the inverting input 112 of the comparator 110; in such case, the switching arrangement should be such that the PWM output signal Sₒᵤₜ is LOW when the input signal Sᵢₙ has a higher voltage level than the feedback signal FB.

FIGS. 2B and 2C illustrate examples of such alternative embodiment. In such a case, an inverting action is required. In the embodiment 100B illustrated in FIG. 2B, an inverter 153 is connected in series with the integrator 150. This inverter 153 may be located before the integrator input 151 of the integrator 150 (as shown), or after the integrator output 152 of the integrator 150. Alternatively, the integrator 150 itself may be of an inverting type.

It is noted that the integrated version of the output signal of comparator 110 corresponds to the input signal, perhaps amplified by a certain gain, and phase-shifted over 180°. If a switching amplifier or buffer is connected to the output terminal 103, either inverting or non-inverting, the influence of a load on the delay generated in the feedback loop 159 can be eliminated such as to obtain a better control over the switching frequency.

In the embodiment 100C illustrated in FIG. 2C, an inverter 154 is connected in series with the output 113 of the comparator 110. Alternatively, the comparator 110 itself may be of an inverting type.

In principle, the output terminal 103 of the PWM generator 100 may be connected directly to the comparator output 113, as illustrated in FIGS. 2A-2C. However, depending on the design of the output stage of the comparator 110 used, it may be desirable to use controllable switches 130 and 140, controlled by the comparator 110, connecting the PWM generator output terminal 103 successively to one of two different supply voltages. This is illustrated in FIG. 4 for the embodiment illustrated in FIG. 2A.

The PWM generator 200 of FIG. 4 comprises a first controllable switch 130 having switch terminals 131 and 132 connected to the generator output terminal 103 and a third supply voltage V3, respectively, and having a control terminal 133 coupled to the comparator output 113. The PWM generator 200 further comprises a second controllable switch 140 having switch terminals 141 and 142 connected to the generator output terminal 103 and a fourth supply voltage V4, respectively, and having a control terminal 143 coupled to the comparator output 113.

It is noted that the third supply voltage V3 will usually be equal to the first supply voltage V1, but this is not absolutely essential. Likewise, the fourth supply voltage V4 will usually be equal to the second supply voltage V2, but this is not absolutely essential.

The two controllable switches each have two operative states: a first or closed state, where a substantially conductive path is present between the switch terminals, and a second or open state, where the switch terminals are substantially not connected to each other. The arrangement of the PWM generator 200 is such that the switches are always in mutually opposite states. If the comparator output 113 is HIGH, the first switch 130 is in its closed state while the second switch 140 is in its open state. Conversely, if the comparator output 113 is LOW, the first switch 130 is in its open state while the second switch 140 is in its closed state.

It may be that the two switches 130 and 140 are of mutually identical design, i.e. their response to the same signal is the same. In that case, they need to receive different control signals S_{c1} and S_{c2}, which are mutually logically opposite. In FIG. 4, this is illustrated by showing an inverter 114 in the path between comparator output 113 and second switch control terminal 143. Although such a design is feasible, in principle, it has the intrinsic disadvantage of a control signal delay introduced by inverter 114, which should be compensated in the path between comparator output 113 and first switch control terminal 133. However, it may be that the comparator 110 used has two output terminals (not shown) which are always mutually opposite, in which case one output terminal will be connected to control the first switch 130 while the other output terminal will be connected to control the second switch 140.

It is also possible that the second switch 140 is of a type such that it is in its open state if the control signal at its control terminal 143 is HIGH. In that case, the two switches can receive the same control signal.

Other solutions are possible, too, as will be clear to a person skilled in the art.

It is noted that controllable switches are known per se, and that conventional controllable switches may be used in implementing the present invention. Therefore, it is not necessary here to discuss the design and operation of a controllable switch in more detail.

FIG. 5 illustrates an alternative embodiment of a PWM generator 300, in which the two controllable switches 130, 140 have been replaced by one controllable switch 160 having three switch terminals 161, 162 and 163, and one control terminal 164 coupled to the comparator output 113. A first switch terminal 161 is connected to the output terminal 103. A second switch terminal 162 is connected to the third supply voltage V3, and a third switch terminal 163 is connected to the fourth supply voltage V4. This controllable switch 160 has two operative states; in a first operative state (HIGH), the first switch terminal 161 assumes the voltage V3 received at the second switch terminal 162, for instance by being connected to the second switch terminal 162, whereas in the second operative state (LOW), the first switch terminal 161 assumes the voltage V4 received at the third switch terminal 163, for instance by being connected to the third switch terminal 163. If the comparator output 113 is HIGH, the switch 160 is in its first state; if the comparator output 113 is LOW, the switch 160 is in its second state.

FIG. 6 illustrates a possible embodiment of the controllable switch 160, which comprises first and second transistors 171 and 172 of PNP type having their emitter connected to the second switch terminal 162, third and fourth transistors 173 and 174 of NPN type having their emitter connected to the third switch terminal 163, and first, second, third, fourth and fifth resistors 175, 176, 177, 178, 179.

The first resistor 175 couples the base of the first transistor 171 to the second switch terminal 162.

The second resistor 176 couples the base of the first transistor 171 to the control terminal 164.

The third resistor 177 couples the base of the third transistor 173 to the control terminal 164.

The fourth resistor 178 couples the base of the third transistor 173 to the third switch terminal 163.

The fifth resistor 179 couples the collector of the first transistor 171 to the collector of the third transistor 173.

The second transistor 172 has its base connected to the collector of the first transistor 171, and has its collector connected to the first switch terminal 161. The fourth transistor 174 has its base connected to the collector of the third transistor 173, and has its collector connected to the first switch terminal 161.

If the control voltage received at the control terminal 164 is HIGH, the first transistor 171 is in a non-conductive state and the third transistor 173 is in a conductive state, and offers a conductive collector-emitter path between the base of the fourth transistor 174 and the third switch terminal 163, so that the fourth transistor 174 is in a non-conductive state. The second transistor 172 is in a conductive state, and offers a conductive collector-emitter path between the first switch terminal 161 and the second switch terminal 162, so that the voltage level at the output terminal 103 is pulled up to the level of the third supply voltage V3 (shown in FIG. 5) by the second transistor 172.

If the control voltage received at the control terminal 164 is LOW, the third transistor 173 is in a non-conductive state and the first transistor 171 is in a conductive state, and offers a conductive collector-emitter path between the base of the second transistor 172 and the second switch terminal 162, so that the second transistor 172 is in a non-conductive state. The fourth transistor 174 is in a conductive state, and offers a conductive collector-emitter path between the first switch terminal 161 and the third switch terminal 163, so that the voltage level at the output terminal 103 is pulled down to the level of the fourth supply voltage V4 (shown in FIG. 5) by the fourth transistor 174.

It is noted that it is also possible to consider the embodiment of FIG. 6 as an implementation of the arrangement of FIG. 4, in that the second and fourth transistors 172 and 174 can be considered as implementing the switches 130 and 140, respectively, as illustrated by the dotted lines in FIG. 6. The respective control signals S_{c1} and S_{c2} are also indicated.

The circuit is designed such that both transistors 172 and 174 are in their non-conductive state during a zero-crossing of the input signal received at the control terminal 164. Thus, a possible short-circuiting between terminals 162 and 163 is prevented. In a possible modification, first and fourth resistors 175 and 178 may be omitted, but the embodiment as shown in FIG. 6 allows better control over the operating points of the transistors.

As mentioned above, in an embodiment where the feedback signal FB is applied to the non-inverting input 111 of the comparator, an inverting action is required. In the embodiment 100B of FIG. 2B an inverter 153 is associated with the feedback integrator 150. In the embodiment 100C of FIG. 2C the inventor 154 is associated with the comparator output 113. In an embodiment involving controllable switches (130, 140; 160) controlled by the comparator output 113, the inverting action may alternatively be provided by the switch or switches.

For such a case, FIG. 7A illustrates a possible, relatively simple embodiment of the controllable switch 160, which comprises an NPN transistor 180 having its collector connected to the first switch terminal 161 and having its emitter connected to the third switch terminal 163. A first resistor 181 couples the collector to the second switch terminal 162. A second resistor 182 couples the transistor base to the third switch terminal 163. A third resistor 183 couples the transistor base to the control terminal 164. If the control voltage received at the control terminal 164 exceeds a certain threshold (i.e. HIGH), determined by the transistor type and by the resistance values of the second and third resistors 182 and 183, the transistor 180 is in a conductive state and offers a conductive collector-emitter path between the first switch terminal 161 and the third switch terminal 163, so that the voltage level at the output terminal 103 is pulled down to the level of the fourth supply voltage V4 (shown in FIG. 5) by the transistor 180. If the control voltage received at the control terminal 164 is below the mentioned threshold, the transistor 180 is in a non-conductive state, so that the voltage level at the output terminal 103 is pulled up to the level of the third supply voltage V3 by the first resistor 181.

FIG. 7B illustrates an alternative to the embodiment illustrated in FIG. 7A, having a symmetrical design, similar to the design of FIG. 6. The resistor 181 has been replaced by a PNP transistor 180′ having its collector connected to the first switch terminal 161 and having its emitter connected to the second switch terminal 162. A resistor 182′ connects the base of transistor 180′ to the second switch terminal 162, while a resistor 183′ connects the transistor 180′ base to the control terminal 164.

FIG. 8 is a diagram illustrating an alternative implementation of a PWM generator 400 according to the present invention. In this case, the input signal Sᵢₙ is received at an inverting input 112 of the comparator 110, whereas a feedback loop 459 is coupled to a non-inverting input 111. A controllable switch is indicated at 160. Between the output terminal 103 and a reference voltage, in this case mass, a series circuit comprising an inductor 451, a capacitor 452 and a resistor 453 is connected. In parallel to the capacitor 452, a loudspeaker system 490 is connected, of which the electric behaviour can be represented by a series circuit comprising a speaker inductor 491 and a speaker resistor 492. The feedback signal FB is taken from the node between capacitor 452 and resistor 453.

The two inductors 451 and 491 and the capacitor 452 together form a second order output filter 450 which, together with the speaker resistor 492, defines a complex load coupled to the output terminal 103. Resistor 453 converts an output current flowing through the load into a voltage feedback signal FB. The feedback is now much less prone to external influences. The output filter 450 also performs the integration, so there is no separate integrator 150 required. Further, resistor 453 is effective as a protection against short-circuiting. The output behaves as a current source, and is more robust.

Thus, the present invention succeeds in providing a low-cost PWM generator 200; 300 which does not require a separate saw-tooth generator and a separate comparator for generating a pulse width a modulated signal. According to the invention, the input signal Sᵢₙ is supplied to one input terminal 112 of a comparator 110, which receives at its other terminal 111 a feedback signal which is derived from the output signal Sₒᵤₜ via integrating means 150, in such a way that the circuit is self-oscillating. More particularly, the feedback signal is such that a HIGH output signal Sₒᵤₜ would, after some delay time as determined by the properties of the integrating means 150, cause the comparator 110 to generate a LOW output signal. The feedback signal is a sloping signal. The comparator switches its output when the feedback signal crosses the level of the input signal, which in turn causes the feedback signal to invert its slope. Thus, the feedback signal in effect provides a saw-tooth signal without being generated by a separate saw-tooth generator.

A further important advantage of the PWM generator proposed by the present invention is that the input impedance may be selected as desired in a wide range. Further, the input of the generator will cause little or no pollution on circuit components connected before the generator, particularly no intermodulation products and EMC.

It should be clear to a person skilled in the art that the present invention is not limited to the exemplary embodiments discussed above, but that various variations and modifications are possible within the protective scope of the invention as defined in the appending claims.

For instance, it is possible to replace the comparator 110 by an operational amplifier (opamp). The phrase “comparator circuit” will be used to cover the implementation of a comparator as well as the implementation of an opamp.

Further, it is possible to use FETs instead of bipolar transistors for implementing the switches.

Further, with reference to FIG. 6, if the stage built around transistors 171 and 173 is considered as a control signal generator for generating control signals S_{C1} and S_{C2} for the switches 130 and 140, such stage may be designed differently.

Further, it is possible to adjust the gain of the generator by a minor modification of the circuit, for instance adding a further resistor in parallel to the capacitor 156 of the feedback integrator 150. As will be clear to a person skilled in the art, the gain G for such case can be expressed as G=1+R1/R2,

wherein R1 is the resistance value of the first resistor 155,

while R2 is the resistance value of the further resistor.

The integrator 150 has a low-pass characteristic with a characteristic cut-off frequency determined by the RC-value of the components 155 and 156, as will be clear to a person skilled in the art. In order to obtain a frequency response which is as flat as possible, it is desirable to supply the input signal Sᵢₙ via a lowpass input filter (not shown) having a cut-off frequency lower than the cut-off frequency of the integrator 150.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. In the device claim enumerating several means, several of these means can be embodied by one and the same item of hardware. The mere fact that certain measures are recited in mutually different dependent claims does not indicate that a combination of these measures cannot be used to advantage.

1. PWM generator having an input terminal for receiving an analog input signal and an output terminal for providing a pulse width modulated output signal, the PWM generator comprising:
a comparator circuit, having a first comparator input coupled to said input terminal, a second comparator input, and a comparator output coupled to said output terminal;
a feedback loop coupled between said output terminal and the second comparator input, the feedback loop comprising a feedback filter for generating a sloping feedback signal when a constant input signal is present at the input terminal.

2. PWM generator according to claim 1, further comprising controllable switching means for connecting said output terminal either to a third supply voltage or to a fourth supply voltage, said controllable switching means being coupled to said output terminal and controlled by at least one control signal derived from an output signal of the comparator circuit.

3. PWM generator according to claim 2, wherein said controllable switching means comprise:
a first controllable switch having a first switch terminal connected to said output terminal, a second switch terminal connected to said third supply voltage, and a control terminal receiving a first control signal of the at least one control signal;
a second controllable switch having a first switch terminal connected to said output terminal, a second switch terminal connected to said fourth supply voltage, and a control terminal receiving a second control signal of the at least one control signal;
wherein each controllable switch has a first operative state wherein the first and second switch terminals are connected to each other, and a second operative state wherein the first and second switch terminals are mutually isolated;
and wherein the first and second control signals are generated such that, depending a voltage level of the output signal of the comparator circuit, either the first controllable switch is in its first operative state while the second controllable switch is in its second operative state, or the first controllable switch is in its second operative state while the second controllable switch is in its first operative state.

4. PWM generator according to claim 3, wherein said first input is a non-inverting input while said second input is an inverting input;
wherein said third supply voltage has a higher voltage level than said fourth supply voltage;
and wherein the first and second control signals are generated such that the first controllable switch is in its first operative state while the second controllable switch is in its second operative state when the output is high, whereas the first controllable switch is in its second operative state while the second controllable switch is in its first operative state when the comparator circuit output is low.

5. PWM generator according to claim 3, wherein said first input is an inverting input while said second input is a non-inverting input;
wherein said third supply voltage has a higher voltage level than said fourth supply voltage;
and wherein the control signals are generated such that the first controllable switch is in its first operative state while the second controllable switch is in its second operative state when the output is low, whereas the first controllable switch is in its second operative state while the second controllable switch is in its first operative state when the comparator circuit output is high.

6. PWM generator according to claim 3, wherein said switching means comprise a controllable switch having a first switch terminal connected to said output terminal, a second switch terminal connected to said third supply voltage, a third switch terminal connected to said fourth supply voltage, and a control terminal receiving a common control signal, being the at least one control signal;
the controllable switch having a first operative state wherein the first switch terminal substantially assumes the voltage received at the second switch terminal and a second operative state wherein the first switch terminal substantially assumes the voltage received at the third switch terminal.

7. PWM generator according to claim 1, wherein said feedback filter comprises: a series circuit comprising an inductor, a capacitor and a resistor connected between the output terminal and a reference voltage.

8. PWM generator according to claim 7, wherein a loudspeaker system is connected in parallel to said capacitor.

9. An electronic apparatus comprising the PWM generator as claimed in claim 7; and connector via which a loudspeaker system is connectable in parallel to said capacitor.
